(19) United States
(12) Patent Application Publication
(10) Pub. No.: US 2026/0343933 A1
(43) Pub. Date: Oct. 29, 2026

(54) SEMICONDUCTOR DEVICE

(71) Applicant: Samsung Electronics Co., Ltd., Suwon-si (KR)

(72) Inventors: Jaekang Koh, Suwon-si (KR); Jinwon Ma, Suwon-si (KR); Sangmin Kang, Suwon-si (KR); Jungpyo Hong, Suwon-si (KR)

(73) Assignee: Samsung Electronics Co., Ltd., Suwon-si (KR)

(21) Appl. No.: 19/578,486

(22) Filed: Mar. 25, 2026

(30) Foreign Application Priority Data
Apr. 29, 2025 (KR) 10-2025-0056447

(51) Int. Cl. H10D 30/47; H10D 30/00; H10D 30/01; H10D 62/80; H10D 64/23; H10D 64/68

(52) U.S. Cl. CPC H10D 30/481; H10D 30/502; H10D 62/882; H10D 62/883; H10D 64/251; H10D 64/685; H10D 64/691; H10D 64/693; H10D 30/017; H10D 30/0191

(57) ABSTRACT

Provided is a semiconductor device, the semiconductor device including a two-dimensional semiconductor layer including a channel region, and contact regions on both sides of the channel region; a gate electrode surrounding the two-dimensional semiconductor layer; a gate insulating layer disposed between the channel region of the two-dimensional semiconductor layer and the gate electrode; a source electrode and a drain electrode respectively disposed in the contact regions of the two-dimensional semiconductor layer; and a contact resistance reduction layer disposed between the contact regions of the two-dimensional semiconductor layer, and the source electrode and the drain electrode, the contact resistance reduction layer including a semiconductor material doped with phosphorus.

### CROSS-REFERENCE TO RELATED APPLICATIONS

This present application claims priority to and the benefit under 35 U.S.C. § 119(a)-(d) of Korean Patent Application No. 10-2025-0056447, filed on Apr. 29, 2025, in the Korean Intellectual Property Office, the entire disclosure of which is incorporated herein by reference.

### FIELD

The present disclosed concepts relate to a semiconductor device including a two-dimensional material.

### BACKGROUND

A transistor is a semiconductor device performing an electrical switching function, and is used in various semiconductor products such as in computer memory, in driving ICs, and the like. As a size of semiconductor devices decreases, the number of semiconductor devices that can be integrated into a single wafer increases, and a driving speed of semiconductor devices also increases, so research is actively being conducted to reduce the size of semiconductor devices.

Recently, research into using a two-dimensional material as a means of reducing the size of semiconductor devices has been conducted. A structure of the transistor used in semiconductor devices has developed from a sheet type to a FINFET structure and then to a Gate all around (GAA) structure.

### SUMMARY

Aspects of the present disclosed concepts are to provide a semiconductor device including a two-dimensional material.

According to aspects of the present disclosed concepts, provided is a semiconductor device, the semiconductor device including a two-dimensional semiconductor layer including a channel region, and contact regions on both sides of the channel region; a gate electrode surrounding the channel region of the two-dimensional semiconductor layer; a gate insulating layer disposed between the channel region of the two-dimensional semiconductor layer and the gate electrode; a source electrode and a drain electrode respectively disposed in the contact regions of the two-dimensional semiconductor layer; and a contact resistance reduction layer disposed between the contact regions of the two-dimensional semiconductor layer, and the source electrode and the drain electrode, the contact resistance reduction layer including a semiconductor material doped with phosphorus.

According to aspects of the present disclosed concepts, provided is a semiconductor device, the semiconductor device including a plurality of two-dimensional semiconductor layers including a channel region doped with phosphorus, and contact regions on both sides of the channel region, respectively; a gate electrode surrounding the channel region of each of the plurality of two-dimensional semiconductor layers; a gate insulating layer disposed between the channel region of each of the plurality of two-dimensional semiconductor layers and the gate electrode, the gate insulating layer including a plurality of dielectric films; and a source electrode and a drain electrode respectively disposed in the contact regions of the plurality of two-dimensional semiconductor layers.

According to aspects of the present disclosed concepts, provided is a semiconductor device, the semiconductor device including a plurality of two-dimensional semiconductor layers including a channel region doped with phosphorus, and contact regions on both sides of the channel region, respectively; a gate electrode surrounding the channel region of each of the plurality of two-dimensional semiconductor layers; a gate insulating layer disposed between the channel region of each of the plurality of two-dimensional semiconductor layers and the gate electrode; a source electrode and a drain electrode disposed in the contact regions of the plurality of two-dimensional semiconductor layers; a contact resistance reduction layer disposed between the contact regions of the plurality of two-dimensional semiconductor layers, and the source electrode and the drain electrode, the contact resistance reduction layer including a semiconductor material doped with phosphorus; and an insulating separation portion disposed between the gate electrode, and the source electrode and the drain electrode in the plurality of two-dimensional semiconductor layers.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a cross-sectional view illustrating a semiconductor device according to example embodiments of the present inventive concept;

FIG. 2 is a plan view illustrating a semiconductor device according to example embodiments of the present inventive concept;

FIG. 3 is a band diagram illustrating a source/drain electrode and a contact region of a channel layer in the semiconductor device of FIG. 1;

FIG. 4 is a graph illustrating the results of X-ray diffraction analysis (XRD) of the contact resistance reduction layer introduced in FIG. 1;

FIGS. 5 to 7 are cross-sectional views illustrating semiconductor devices according to various embodiments of the present inventive concept;

FIGS. 8A to 8H are cross-sectional views of major processes, illustrating a method for manufacturing a semiconductor device according to example embodiments of the present inventive concept;

FIGS. 9A to 9F are cross-sectional views of major processes, illustrating a method for manufacturing a semiconductor device according to example embodiments of the present inventive concept;

FIGS. 10A to 10F are cross-sectional views of major processes, illustrating a method for manufacturing a semiconductor device according to example embodiments of the present inventive concept; and

FIGS. 11A to 11H are cross-sectional views of major processes, illustrating a method for manufacturing a semiconductor device according to example embodiments of the present inventive concept.

### DETAILED DESCRIPTION

Hereinafter, various example embodiments of the present inventive concept will be described in detail with reference to the attached drawings.

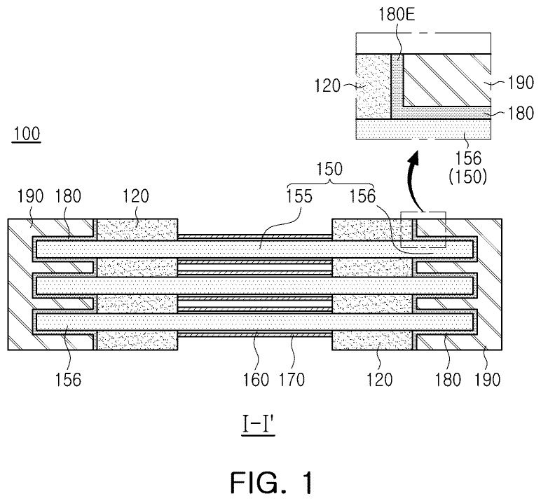

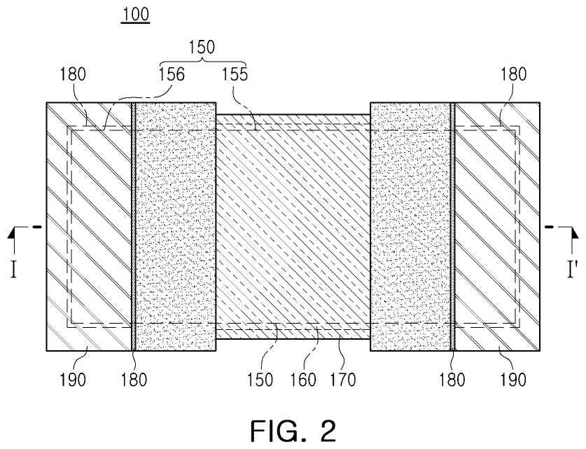

FIG. 1 is a cross-sectional view illustrating a semiconductor device according to example embodiments of the present inventive concept, and FIG. 2 is a plan view illustrating a semiconductor device according to example embodiments of the present inventive concept.

Referring to FIGS. 1 and 2, a semiconductor device 100 according to the present embodiment may include a plurality of two-dimensional semiconductor layers 150, respectively having a channel region 155 and contact regions 156, a gate electrode 170 surrounding the channel region 155, a gate insulating layer 160 between the channel region 155 and the gate electrode 170, and source and drain electrodes 190 respectively disposed in the contact regions 156.

The semiconductor device 100 according to the present embodiment is a type of gate all around (GAA) transistor, and is exemplified as a multi-bridge channel FET in which a plurality of plate-shaped two-dimensional semiconductor layers 150 (i.e., channel layers) are stacked.

Each of the plurality of two-dimensional semiconductor layers 150 provides a channel structure of the semiconductor device 100. The two-dimensional semiconductor layer 150 employed in the present embodiment may include a two-dimensional semiconductor material in the form of a nanosheet. The two-dimensional semiconductor material refers to a material having a layered structure to which constituent atoms are two-dimensionally bonded. The two-dimensional semiconductor layer 150 may have a monolayer or multilayer structure, and for example, the multilayer two-dimensional semiconductor layer 150 may include 1 to 10 layers, but example embodiments thereof is not limited thereto. Here, each layer may have a thickness at an atomic level.

A two-dimensional semiconductor material may have semiconductor characteristics and maintain excellent electrical characteristics even when the two-dimensional semiconductor material has a thin thickness in the nanoscale. For example, the two-dimensional semiconductor material may have a band gap of about 0.1 eV to about 3.0 eV or less.

The two-dimensional semiconductor material may include a transition metal dichalcogenide (TMD). TMD is a compound of a transition metal and a chalcogen element. Here, the transition metal may include, for example, at least one of Mo, W, Nb, V, Ta, Ti, Zr, Hf, Co, Tc and Re, and the chalcogen element may include, for example, at least one of S, Se and Te. For example, TMD may include MOS₂, MoSe₂, MoTe₂, WS₂, WSe₂, WTe₂, ZrS₂, ZrSe₂, HfS₂, HfSe₂, NbSe₂, ReSe₂, or the like. However, example embodiments thereof is not limited thereto. In some example embodiments, the two-dimensional semiconductor material may include graphene, hexagonal boron nitride (h-BN), or black phosphorus. Graphene and black phosphorus are semiconductor materials having a two-dimensionally bonded structure of phosphorus (P) atoms and carbon atoms, respectively.

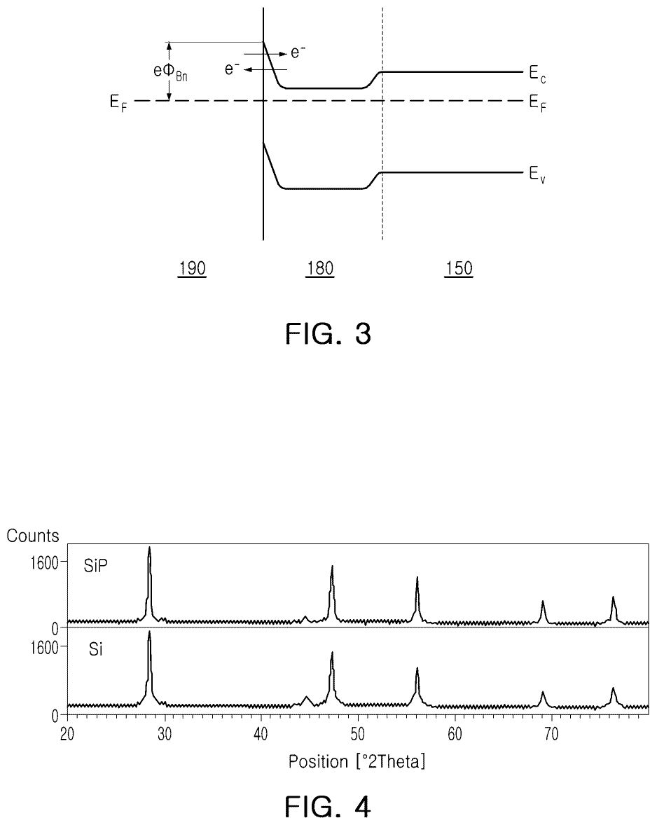

The two-dimensional semiconductor material may be doped with a P-type dopant or an N-type dopant to control the mobility, and for example, by doping with phosphorus, the two-dimensional semiconductor layer may be provided as a P-type semiconductor layer. The new P-type doping method is described in detail in example embodiments illustrated in FIG. 3.

The semiconductor device 100 according to the present embodiment may include a plurality of two-dimensional semiconductor layers 150. Each of the plurality of two-dimensional semiconductor layers 150 may include a channel region 155 provided as a channel structure, and contact regions 156 on both sides of the channel region 155.

The gate electrode 170 may be formed to surround the channel region 155 of each two-dimensional semiconductor layer 150. The gate electrode 170 may be formed to surround entire outer surfaces of the channel region 155 in one direction, but example embodiments thereof is not limited thereto, and may be formed to surround only a portion of the outer surfaces of the channel region 155.

The gate electrode 170 may include a metal material or a conductive oxide. Here, the metal material may include at least one of, for example, Au, Ti, TiN, TaN, W, Mo, WN, Pt, and Ni. For example, the conductive oxide may include Indium Tin Oxide (ITO), Indium Zinc Oxide (IZO), or the like.

A gate insulating layer 160 may be disposed between the channel region 155 of the two-dimensional semiconductor layer 150 and the gate electrode 170. The gate insulating layer 160 may include at least one dielectric film. For example, the gate insulating layer 160 may include at least one of silicon oxide, silicon nitride, aluminum oxide (Al₂O₃), hafnium oxide (HfO₂), and zirconium oxide (ZrO₂), but example embodiments thereof is not limited thereto and may include various dielectric materials.

Source and drain electrodes 190 may be disposed in contact regions 156 of each of the plurality of two-dimensional semiconductor layers 150. For example, each of the source and drain electrodes 190 may include a metal material such as Ag, Au, Pt, or Cu.

The semiconductor device 100 according to the present embodiment may further include a contact resistance reduction layer 180 between the contact regions 156 and the source and drain electrodes 190.

When a metal of the source/drain electrodes 190 and the two-dimensional semiconductor layer 150 are in direct contact, a Schottky barrier may be formed, which may increase contact resistance. In particular, the two-dimensional semiconductor material has weak surface bonding, is difficult to dope, making it difficult to lower the contact resistance. To solve such a problem, in the present embodiment, a contact resistance reduction layer 180 may be introduced as a work function adjustment layer. The contact resistance reduction layer 180 may include a semiconductor material doped with phosphorus. For example, the contact resistance reduction layer 180 may include silicon phosphide (SiP). For example, the thickness of the contact resistance reduction layer 180 may be in a range of 1 nm to 10 nm.

FIG. 3 illustrates a band diagram near a contact interface into which a contact resistance reduction layer is introduced.

Referring to FIG. 3, since the contact resistance reduction layer 180 has an appropriate work function, a Shottky barrier height may be reduced and a tunneling probability may be increased by rearranging bands between source/drain electrodes 190 (e.g., metal) and a two-dimensional semiconductor layer 150. This can effectively reduce the contact resistance between the source/drain electrodes 190 and the two-dimensional semiconductor layer 150.

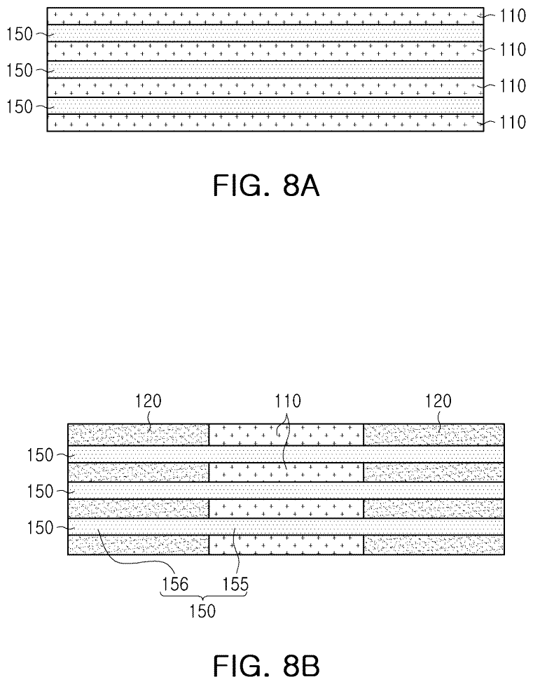

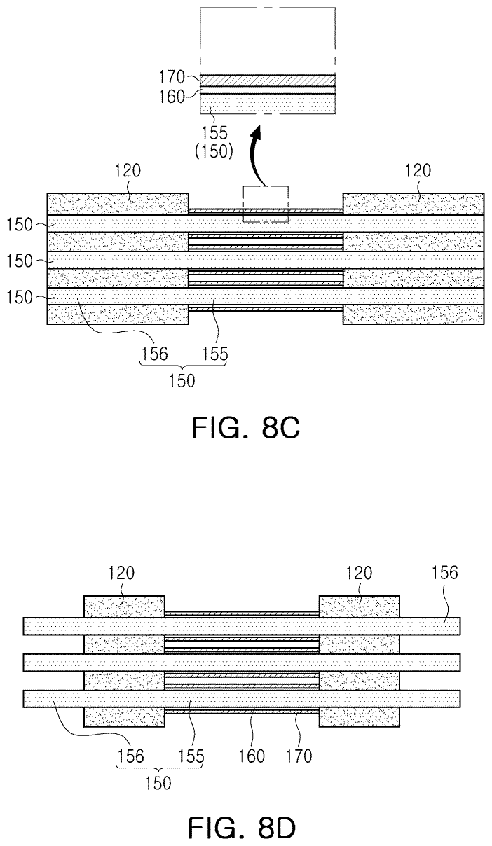

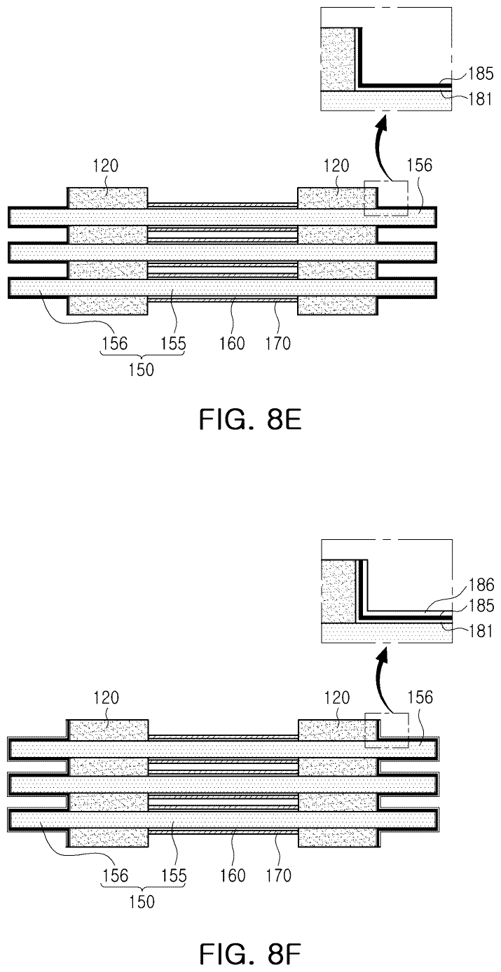

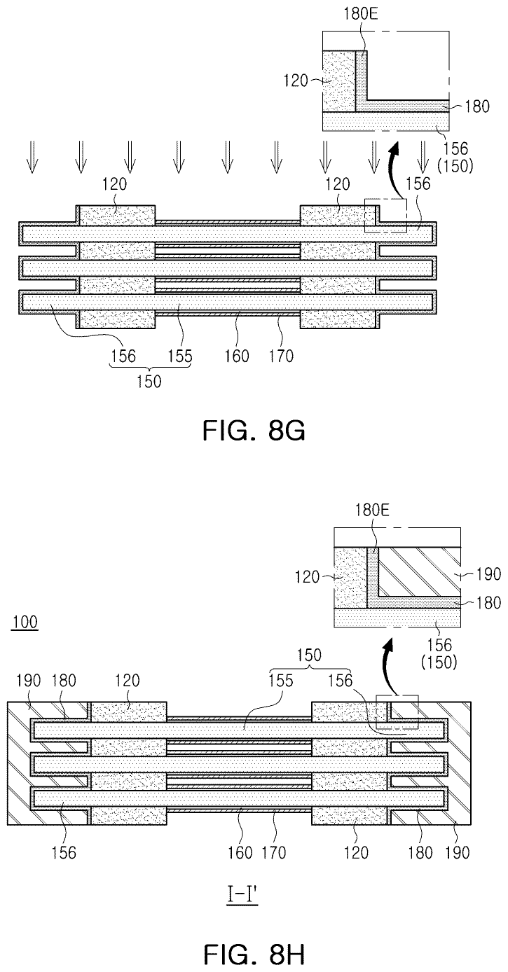

In addition, in the process of forming a contact resistance reduction layer 180 (see FIGS. 8E to 8G), contact interface defects caused by the two-dimensional semiconductor layer 150 may also be improved. The contact resistance reduction layer 180 may include silicon doped with phosphorus, i.e., SiP. In addition, in the present embodiment, the contact resistance reduction layer 180 may have a portion 180E extended to an outer wall of the insulating separation portion 120. In addition, in the process of forming the contact resistance reduction layer, which is SiP, the contact regions 156 of the two-dimensional semiconductor layer 150 may also have a region doped with phosphorus.

FIG. 4 illustrates the results of X-ray diffraction (XRD) analysis of SiP and silicon used as a contact resistance reduction layer 180 in the present embodiment.

Referring to FIG. 4, it is illustrated that SiP has almost the same crystal peak as silicon, thereby confirming that SiP formed according to the present embodiment maintains the same crystal structure as silicon. The contact resistance reduction layer 180 employed in the present embodiment can use a method of utilizing a silicon capping layer. This will be described in detail in the subsequent manufacturing method (see FIGS. 8E to 8G).

An insulating separation portion 120 may be disposed to surround the two-dimensional semiconductor layer 150 between the gate electrode 170 and the source/drain electrodes 190. For example, the insulating separation portion 120 may include silicon oxide, silicon oxynitride, silicon nitride, silicon carbide, or silicon carbonate.

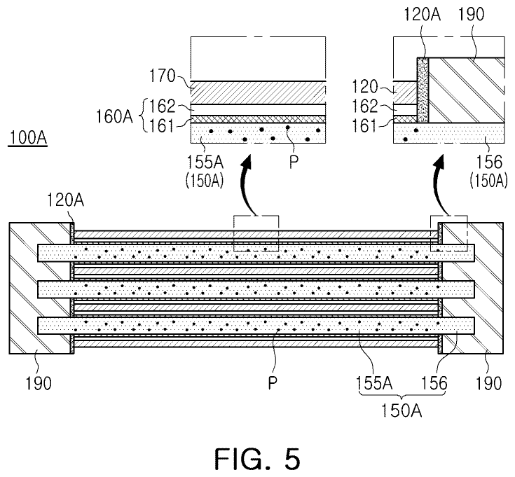

FIG. 5 is a cross-sectional view illustrating a semiconductor device according to example embodiments of the present inventive concept.

Referring to FIG. 5, it can be understood that a semiconductor device 100A according to the present embodiment is similar to the semiconductor device 100 illustrated in FIGS. 1 and 2, except for the fact that a two-dimensional semiconductor layer 150A is doped with phosphorus (P), instead of introducing the contact resistance reduction layer (180 in FIG. 2), an insulating barrier 120A is included, instead of the insulating separation portion (120 in FIG. 1), and a gate insulating layer 160A has a multilayer structure. In addition, the components of the present embodiment may be understood by referring to the description of the same or similar components of the semiconductor device 100 illustrated in FIGS. 1 and 2, unless otherwise specifically stated.

The semiconductor device 100A according to the present embodiment may include a two-dimensional semiconductor layer 150A doped with phosphorus (P), instead of introducing a contact resistance reduction layer (180 in FIG. 2). The two-dimensional semiconductor layer 150A may include a channel region 155A doped with phosphorus (P). The mobility of the channel region 155A may be significantly improved by phosphorus doping. In this embodiment, the two-dimensional semiconductor layer 150A may be provided as a P-type semiconductor layer.

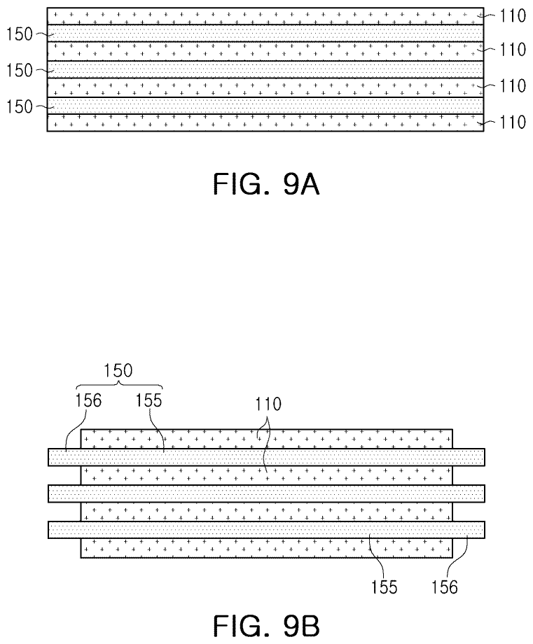

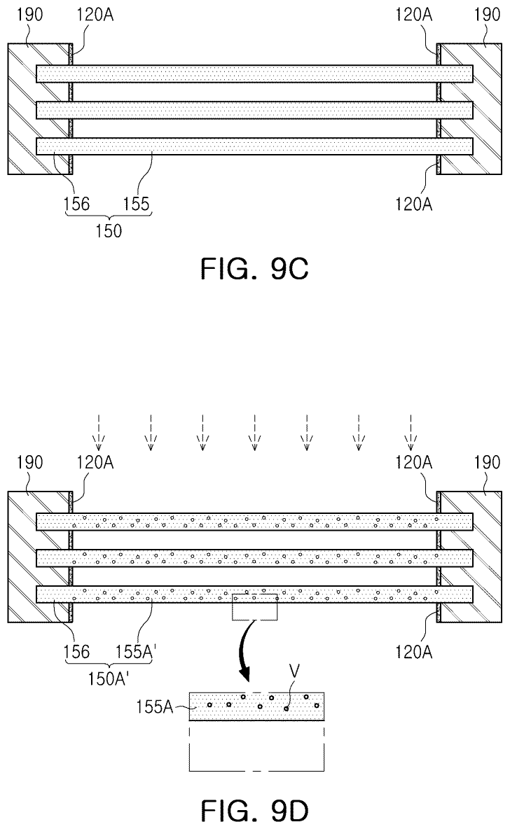

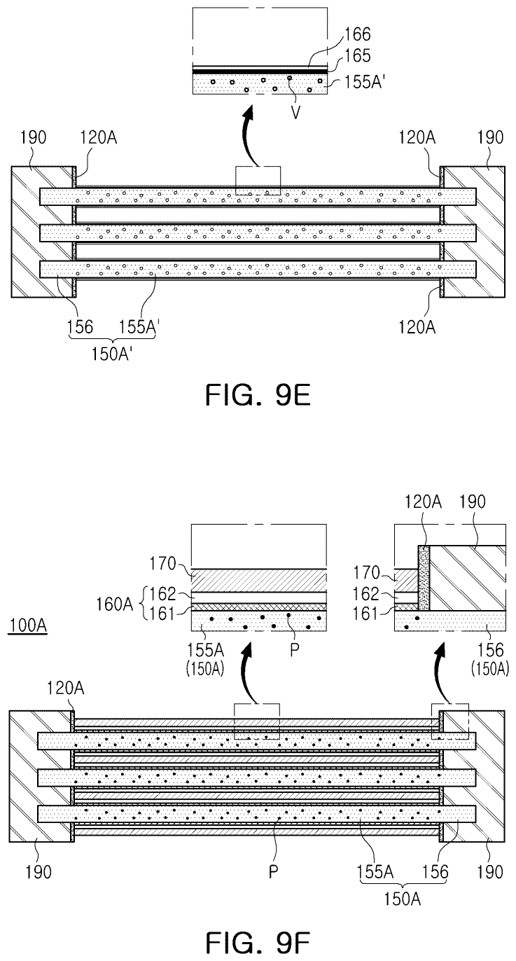

As described above, the two-dimensional semiconductor layer 150A has a layered structure at an atomic layer level, and includes one to several layers, so it is difficult to be doped with a dopant. For example, the two-dimensional semiconductor layer 150A is very thin, and has surface conditions that make it difficult to bond with a dopant (e.g., absence of dangling bonds), making it difficult to perform effective doping. To this end, doping of the two-dimensional semiconductor layer 150A may be effectively performed by applying a capping layer after phosphorus deposition together with plasma processing of the two-dimensional semiconductor layer 150A. This process will be described in detail in FIGS. 9A to 9F. In the present embodiment, the contact regions 156 of each of the plurality of two-dimensional semiconductor layers 150A may include a two-dimensional semiconductor material, not doped with phosphorus.

The gate insulating layer 160A may include a plurality of dielectric films 161 and 162. The gate insulating layer 160A employed in the present embodiment may include a first dielectric film 161 in contact with a surface of the channel region 155A and a second dielectric film 162 on the first dielectric film 161. In the present embodiment, the first dielectric film 161 may be a layer obtained from a capping layer (166 of FIG. 9E) for doping phosphorus into the channel region 155A. For example, the first dielectric film 161 may be a silicon compound layer, and the second dielectric film 162 may include a material different from the first dielectric film 161. In some example embodiments, the first dielectric film 161 may include silicon phosphide (SiP), silicon oxide, silicon oxynitride, or silicon nitride. The second dielectric film 162 may include aluminum oxide (Al₂O₃), hafnium oxide (HfO₂), or zirconium oxide (ZrO₂).

The insulating separation structure employed in the present embodiment may include an insulating barrier 120A between the gate electrode 170 and the source/drain electrodes 190. The insulating barrier 120A may have a relatively thinner thickness than the insulating separation portion of the previous embodiment. The insulating barrier 120A may be formed on both side walls of the gate electrode 170 or on the facing inner side walls of the source and drain electrodes 190. For example, the insulating barrier 120A may include silicon oxide, silicon oxynitride, silicon nitride, silicon carbide, or silicon carbonate.

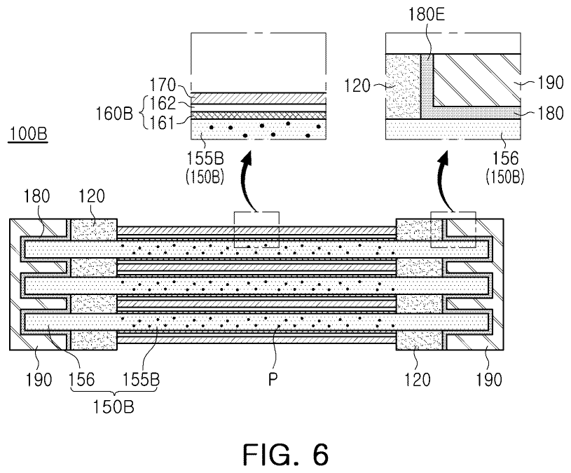

FIG. 6 is a cross-sectional view illustrating a semiconductor device according to example embodiments of the present inventive concept.

Referring to FIG. 6, it can be understood that a semiconductor device 100B according to the present embodiment is similar to the semiconductor device 100 illustrated in FIGS. 1 and 2, except for the fact that two-dimensional semiconductor layer 150B is doped with phosphorus (P) together with the contact resistance reduction layer 180, and the gate insulating layer 160B has a multilayer structure. In addition, the components of the present embodiment may be understood by referring to the description of the same or similar components of the semiconductor device 100 illustrated in FIGS. 1 and 2, unless otherwise specifically stated.

The semiconductor device 100B according to the present embodiment may include a two-dimensional semiconductor layer 150B doped with phosphorus (P) for improving channel mobility, together with a contact resistance reduction layer 180.

The contact resistance reduction layer 180 may include a semiconductor material doped with phosphorus, and may be introduced between the source/drain electrodes 190 and the two-dimensional semiconductor layer 150 to lower a Schottky barrier and improve contact resistance. For example, the contact resistance reduction layer 180 may include silicon phosphide (SiP). For example, a thickness of the contact resistance reduction layer 180 may be in a range of 1 nm to 10 nm.

The two-dimensional semiconductor layer 150B may include a channel region 155B doped with phosphorus (P). The two-dimensional semiconductor layer 150B may be effectively doped with phosphorus (P) by applying a capping layer after phosphorus deposition together with plasma processing.

The gate insulating layer 160B employed in this embodiment may include a first dielectric film 161 contacting the surface of the channel region 155B and a second dielectric film 162 on the first dielectric film 161. In the present embodiment, the first dielectric film 161 may be a layer obtained from a capping layer for doping phosphorus into the channel region 155B. For example, the first dielectric film 161 may include silicon phosphide (SiP), silicon oxide, silicon oxynitride, or silicon nitride. For example, the second dielectric film 162 may include aluminum oxide (Al₂O₃), hafnium oxide (HfO₂), or zirconium oxide (ZrO₂).

The insulating separation structure employed in the present embodiment may include an insulating separation portion 120 between the gate electrode 170 and the source/drain electrodes 190 to surround the two-dimensional semiconductor layer 150B. For example, the insulating separation portion 120 may include silicon oxide, silicon oxynitride, silicon nitride, silicon carbide, or silicon carbonate.

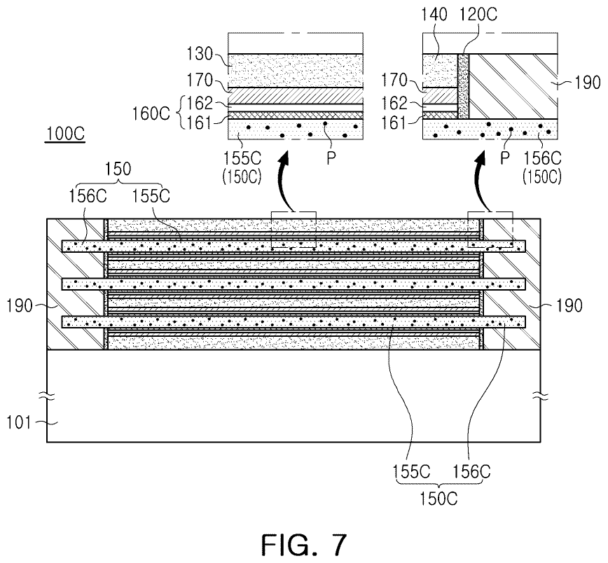

FIG. 7 is a cross-sectional view illustrating a semiconductor device according to example embodiments of the present inventive concept.

Referring to FIG. 7, it can be understood that a semiconductor device 100C according to the present embodiment is similar to the semiconductor device 100 illustrated in FIGS. 1 and 2, except for the fact that the two-dimensional semiconductor layer 150C is almost entirely doped with phosphorus (P), instead of the contact resistance reduction layer 180 on the substrate 101, and the gate insulating layer 160C has a multilayer structure. In addition, the components of the present embodiment may be understood by referring to the description of the same or similar components of the semiconductor device 100 illustrated in FIGS. 1 and 2, unless otherwise specifically stated.

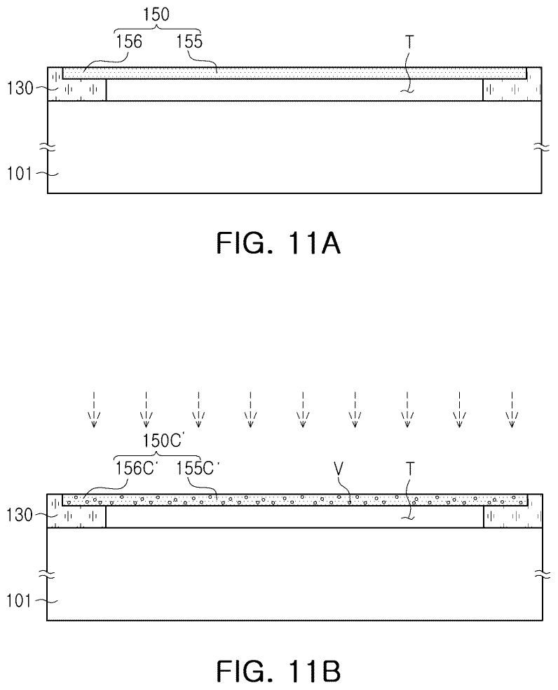

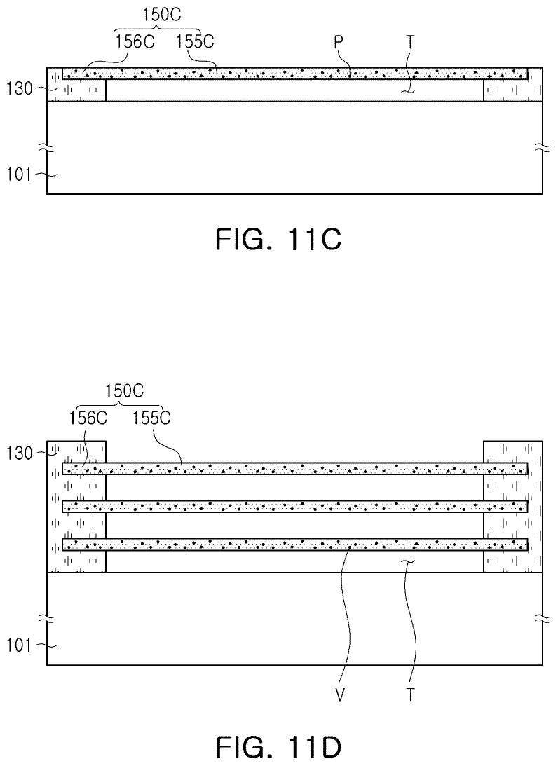

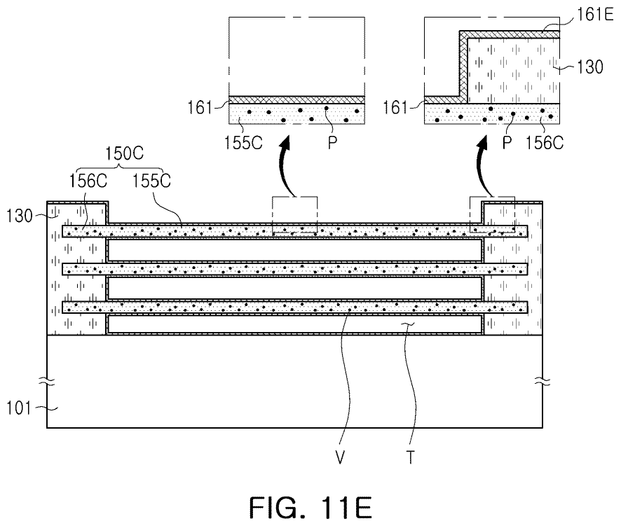

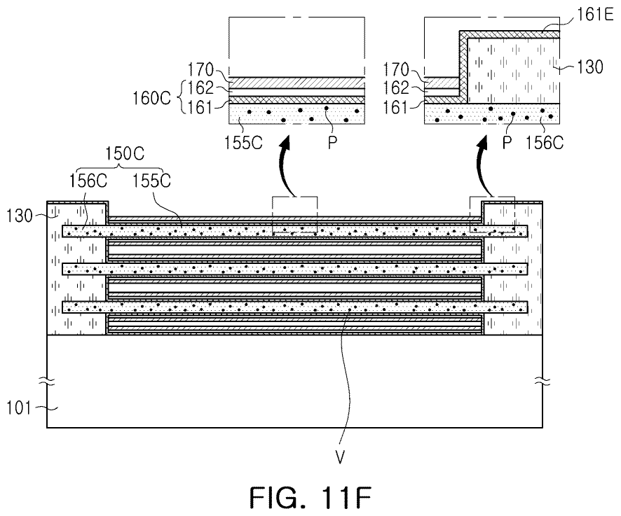

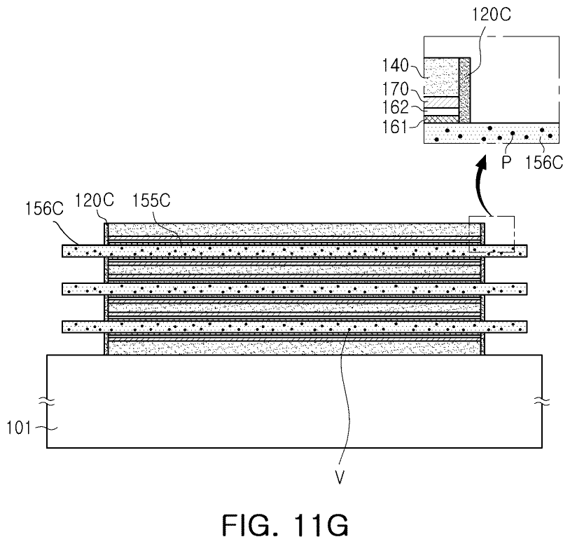

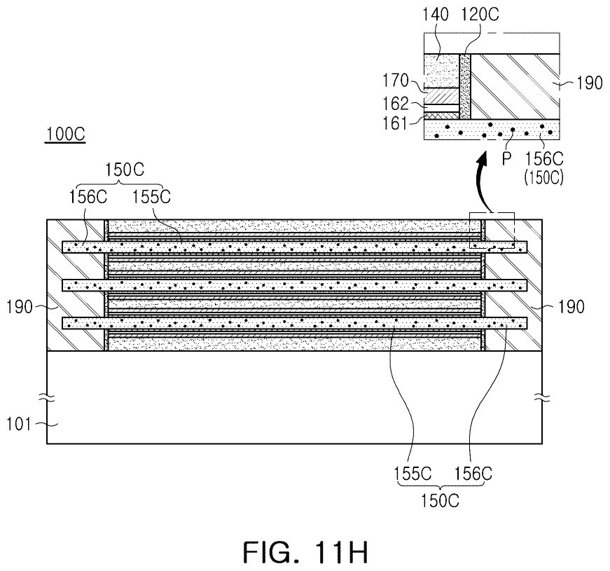

In the present embodiment, a plurality of two-dimensional semiconductor layers 150C are stacked on the substrate 101 vertically, and phosphorus (P) may be doped over almost the entire region. That is, not only the channel region 155C but also the contact regions 156C may be doped with phosphorus (P). In the present embodiment, not only may the mobility be improved in the channel region 155C, but also the contact resistance with the source/drain electrodes 190 in the contact regions 156C may be reduced. Such phosphorus (P) doping may be performed by applying a capping layer after phosphorus deposition, together with plasma processing, similar to the previous embodiment (see FIGS. 11A to 11D).

The gate insulating layer 160C employed in this embodiment may include a first dielectric film 161 contacting the surface of the channel region 155C and a second dielectric film 162 on the first dielectric film 161. In the present embodiment, the first dielectric film 161 may be a layer obtained from a capping layer for doping phosphorus into the channel region 155C. For example, the first dielectric film 161 may include silicon phosphide (SiP), silicon oxide, silicon oxynitride, or silicon nitride. For example, the second dielectric film 162 may include aluminum oxide (Al₂O₃), hafnium oxide (HfO₂), or zirconium oxide (ZrO₂).

The insulating separation structure employed in the present embodiment may include an insulating barrier 120C between the gate electrode 170 and the source/drain electrodes 190. The insulating barrier 120C may be formed on both sidewalls of the gate electrode 170 or on the facing inner side walls of the source and drain electrodes 190. For example, the insulating barrier 120C may include silicon oxide, silicon oxynitride, silicon nitride, silicon carbide, or silicon carbonate.

Additionally, an insulating filling portion 140 may be formed as a protective layer around the channel region 155C surrounded by the gate electrode 170. For example, the insulating filling portion 140 may include Flowable Oxide (FOX), Tonen SilaZen (TOSZ), Undoped Silica Glass (USG), Borosilica Glass (BSG), PhosphoSilaca Glass (PSG), BoroPhosphoSilica Glass (BPSG), Plasma Enhanced Tetra Ethyl Ortho Silicate (PETEOS), Fluoride Silicate Glass (FSG), High Density Plasma (HDP) oxide, Plasma Enhanced Oxide (PEOX), Flowable CVD (FCVD) oxide, or a combination thereof. The insulating filling portion 140 may be formed using a chemical vapor deposition (CVD), a flowable-CVD process, or a spin coating process.

FIGS. 8A to 8H are cross-sectional views of major processes, illustrating a method for manufacturing a semiconductor device according to example embodiments of the present inventive concept, and may be understood as, for example, the method for manufacturing the semiconductor device 100 of FIG. 2.

Referring to FIG. 8A, a plurality of sacrificial layers 110 and a plurality of two-dimensional semiconductor layers 150 may be alternately stacked.

Each of the plurality of semiconductor layers 150 may include a two-dimensional semiconductor material as described in FIGS. 1 and 2. For example, the two-dimensional semiconductor material may include MOS₂, MoSe₂, MoTe₂, WS₂, WSe₂, WTe₂, ZrS₂, ZrSe₂, HfS₂, HfSe₂, NbSe₂, and ReSe₂, or may include graphene, h-BN, or black phosphorus. The plurality of sacrificial layers 110 may include a material having high selectivity with the two-dimensional semiconductor layer 150 and a material that can be selectively removed in the manufacturing process of the semiconductor device. For example, the sacrificial layer 110 may include silicon oxide, aluminum oxide (Al₂O₃), hafnium oxide (HfO₂), or zirconium oxide (ZrO₂). A plurality of sacrificial layers 110 and a plurality of two-dimensional semiconductor layers 150 may be formed by a deposition process such as chemical vapor deposition (CVD) or physical vapor deposition (PVD).

Next, referring to FIG. 8B, the sacrificial layer 110 may be partially removed and an insulating separation portion 120 may be formed in the removed spaces.

The partial removal of the sacrificial layer 110 may be performed so that contact regions 156 located at both ends of the plurality of two-dimensional semiconductor layers 150 are exposed. The sacrificial layer 110 may be removed at least in a region excluding the channel region 155. Such a removal may be performed by wet etching using hydrogen fluoride (HF) and dry etching using tetrafluoromethane gas.

An insulating separation portion 120 may be formed in the removed spaces. The insulating separation portion 120 may be formed of another insulating material having high selectivity with respect to the two-dimensional semiconductor layer 150 and the remaining sacrificial layer 110. For example, the insulating separation portion 120 may include silicon oxide, silicon oxynitride, silicon nitride, silicon carbide, or silicon carbonate.

Next, referring to FIG. 8C, the remaining sacrificial layer 110 may be removed, and a gate insulating layer 160 and a gate electrode 170 may be sequentially formed in the channel region 155 of the two-dimensional semiconductor layer 150.

By selectively removing the remaining sacrificial layer 110, the channel region 155 of the two-dimensional semiconductor layer 150 may be opened. A gate insulating layer 160 and a gate electrode 170 may be sequentially deposited in the open channel region 155. This deposition process may be performed by a deposition process such as chemical vapor deposition (CVD) or physical vapor deposition (PVD).

The gate electrode 170 may include a metal material or a conductive oxide. Here, the metal material may include, for example, at least one of Au, Ti, TiN, TaN, W, Mo, WN, Pt, and Ni. For example, the conductive oxide may include Indium Tin Oxide (ITO), Indium Zinc Oxide (IZO), or the like. The gate insulating layer 160 may include at least one dielectric film. For example, the gate insulating layer 160 may include at least one of silicon oxide, silicon nitride, aluminum oxide (Al₂O₃), hafnium oxide (HfO₂), and zirconium oxide (ZrO₂).

Next, referring to FIG. 8D, the contact regions 156 of the two-dimensional semiconductor layers 150 may be opened by partially removing both end regions of the insulating separation portion 120. Next, referring to FIG. 8E, a phosphorus film 185 may be deposited on the open contact regions 156.

In this process, in the deposition process of the phosphorus film 185, the desired phosphorus film 185 may be deposited more stably by depositing a phosphorus precursor 181 in the contact regions 156 of the two-dimensional semiconductor layer 150 in advance. For example, the phosphorus precursor 181 may include Diisopropylaminosilane (DIPAS), and may be deposited by plasma enhanced chemical vapor deposition (PECVD). The deposition process of the phosphorus film 185 may include various deposition processes using at least one of PH₃, P₂O₅, and P₂O₃. Various deposition processes may include thermal evaporating, E-beam evaporating, physical vapor deposition (PVD), chemical vapor deposition (CVD), atomic layer deposition (ALD), and molecular layer deposition (MLD). In some example embodiments, the phosphor precursor 181 and the phosphorus film 185 may be formed not only on surfaces of the contact regions 156, but also on an outer side wall of the insulating separation portion 120.

Next, referring to FIG. 8F, a silicon capping layer 186 may be formed on the deposited phosphorus film 185, and then, referring to FIG. 8G, an annealing process may be applied to the phosphorus film 185 covered with the silicon capping layer 186.

In the annealing process, the silicon capping layer 186 may prevent the phosphorus element deposited on the contact regions 156 from being out-diffused. The contact regions 156 of the two-dimensional semiconductor layer 150 may be effectively doped. In addition, during an annealing process (e.g., at 300 °C or higher), phosphorus may diffuse into the silicon capping layer 186 to form a contact resistance reduction layer 180 including SiP. In the present embodiment, the contact resistance reduction layer 180 may have a portion 180E extending to a side surface of the insulating separation portion 120.

Next, referring to FIG. 8H, source and drain electrodes 190 may be formed on the contact resistance reduction layer 180.

For example, each of the source and drain electrodes 190 may include a metal material such as Ag, Au, Pt, or Cu. The contact resistance reduction layer 180 may effectively reduce the contact resistance between the source/drain electrodes 190 and the two-dimensional semiconductor layer 150.

FIGS. 9A to 9F are cross-sectional views of major processes, illustrating a method for manufacturing a semiconductor device according to example embodiments of the present inventive concept, and can be understood as, for example, the method for manufacturing the semiconductor device 100A of FIG. 5.

Referring to FIG. 9A, a plurality of sacrificial layers 110 and a plurality of two-dimensional semiconductor layers 150 may be alternately stacked.

The present process may be performed similarly to the process described in FIG. 8A. Each of the plurality of semiconductor layers 150 may include a two-dimensional semiconductor material, and the plurality of sacrificial layers 110 may include silicon oxide, aluminum oxide (Al₂O₃), hafnium oxide (HfO₂), or zirconium oxide (ZrO₂) as a material having high selectivity with the two-dimensional semiconductor layer 150. A plurality of sacrificial layers 110 and a plurality of two-dimensional semiconductor layers 150 may be formed by a deposition process such as chemical vapor deposition (CVD) or physical vapor deposition (PVD).

Next, referring to FIG. 9B, the sacrificial layer 110 may be partially removed so that the contact regions 156 are opened. Next, referring to FIG. 9C, after forming source/drain electrodes 190 in the removed spaces, the remaining sacrificial layer 110 may be removed to open the channel region 155.

The partial removal of the sacrificial layer 110 may be performed so that contact regions 156 located at both ends of the plurality of two-dimensional semiconductor layers 150 are exposed. The sacrificial layer removal process may be performed by wet etching or dry etching. In the present embodiment, an insulating barrier 120A may be formed on an outer side wall of the sacrificial layer 110 remaining therein. For example, the insulating barrier 120A may include an insulating material having high selectivity with respect to the sacrificial layer 110. For example, the insulating barrier 120A may include silicon oxide, silicon oxynitride, silicon nitride, silicon carbide, or silicon carbonate. After forming the insulating barrier 120A, source/drain electrodes 190 may be formed in the contact regions, and the remaining sacrificial layer 110 may be removed to open the channel region 155.

Next, referring to FIG. 9D, an open channel region 155A′ of two-dimensional semiconductor layers 150A′ may be processed with plasma.

A void (V) may be formed in the channel region 155A′ by the present plasma processing. The void (V) may be provided as a site for phosphorus to be diffused in a subsequent process. The plasma may include Ar, H₂, and/or O₂ plasma.

Next, referring to FIG. 9E, a phosphorus film 165 may be deposited on the channel region 155A′, and a capping layer 166 may be formed on the deposited phosphorus film 165.

A deposition process of the phosphorus film 165 may be performed by various deposition processes using at least one of PH₃, P₂O₅, and P₂O₃. Various deposition processes may include thermal evaporating, electron beam evaporating, physical vapor deposition (PVD), chemical vapor deposition (CVD), atomic layer deposition (ALD), and molecular layer deposition (MLD). In the process of forming such a phosphorus film, phosphorus may be easily diffused into the interior of the plasma-processed channel region 155A′. In some example embodiments, a phosphorus precursor (e.g., DIPAS) in the channel region 155A′ of the two-dimensional semiconductor layer 150A′ in advance, before the deposition of the phosphorus film 185 (see FIG. 8E).

Next, a capping layer 166 may be formed on the deposited phosphorus film 165. In the present embodiment, the capping layer 166 is exemplified as silicon, but in some embodiments, the capping layer 166 may include other silicon compounds. For example, the silicon compound can include silicon oxide, silicon oxynitride, or silicon nitride.

In the present embodiment, by applying an additional annealing process, phosphorus elements may be sufficiently diffused from the phosphorus film 165 into the interior of the channel region 155A′. The capping layer 166 may form SiP by phosphorus diffusion. SiP can be provided as a portion of the gate insulating layer 160, as a first dielectric film (161 of FIG. 9F). The annealing process may be applied prior to the process of FIG. 9F, but in some example embodiments, the annealing process may be replaced with an annealing process for a gate insulating layer and a gate electrode.

Next, referring to FIG. 9F, a second dielectric film 162 and a gate electrode 170 may be sequentially formed on a first dielectric film 161 of the channel region 155A of the two-dimensional semiconductor layer 150A.

A second dielectric film 162 may be formed on the first dielectric film 161 to form a desired gate insulating layer 160A. Then, a gate electrode 170 may be formed on the gate insulating layer 160A. For example, the second dielectric film 162 may include at least one of aluminum oxide (Al₂O₃), hafnium oxide (HfO₂), and zirconium oxide (ZrO₂). The gate electrode 170 may include a metal material or a conductive oxide. For example, the metal material may include at least one of Au, Ti, TiN, TaN, W, Mo, WN, Pt, and Ni.

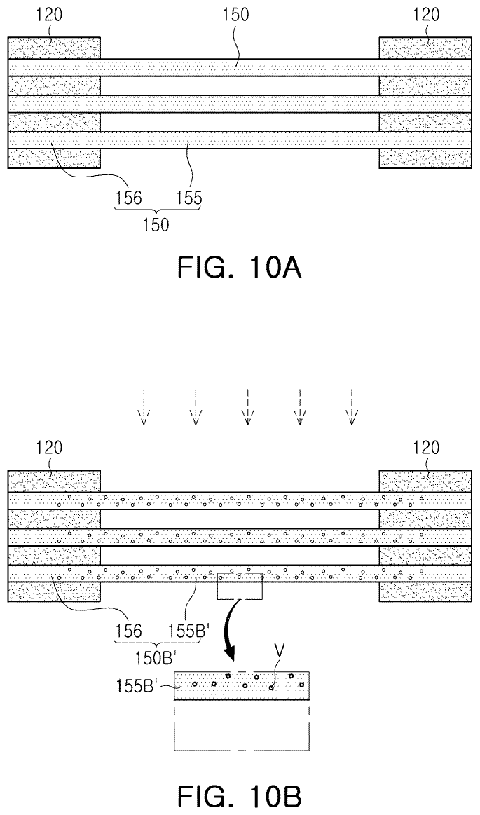

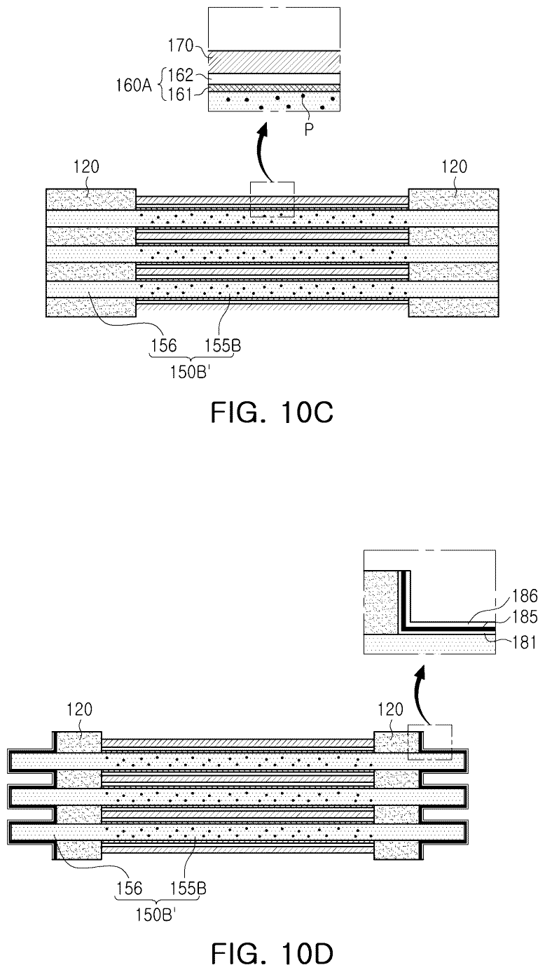

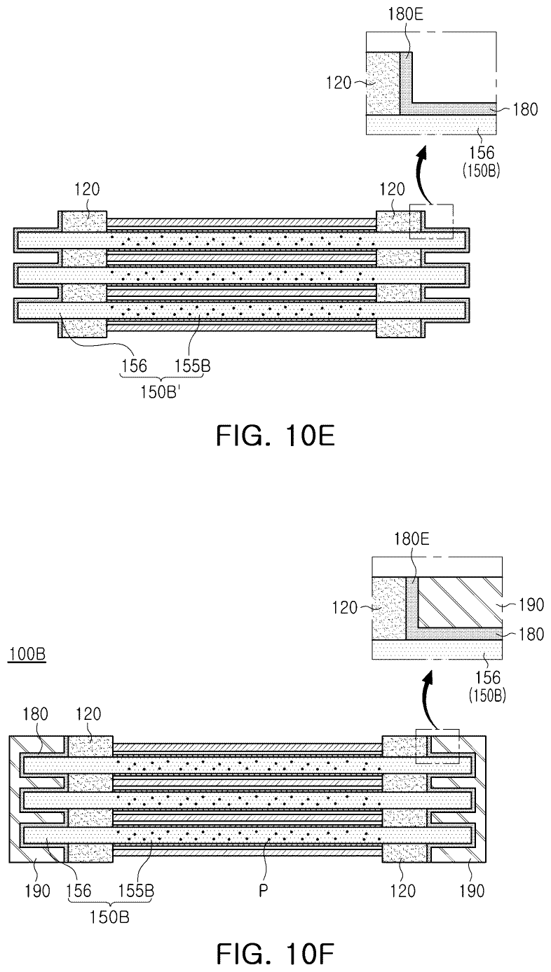

FIGS. 10A to 10F are cross-sectional views of major processes, illustrating a method for manufacturing a semiconductor device according to example embodiments of the present inventive concept, and can be understood as, for example, the method for manufacturing the semiconductor device 100B of FIG. 6.

Referring to FIG. 10A, an insulating separation portion may be formed at both ends of two-dimensional semiconductor layers, and a structure having an open channel region may be formed.

In such a structure, as illustrated in FIG. 8A, a plurality of sacrificial layers 110 and a plurality of two-dimensional semiconductor layers 150 are alternately stacked (see FIG. 8A), and then the sacrificial layers 110 may be partially removed so that the contact regions 156 located at both ends of the plurality of two-dimensional semiconductor layers 150 are opened, and an insulating separation portion 120 may be formed in the removed spaces (see FIG. 8B). Next, the remaining sacrificial layer 110 may be removed to open channel regions 155 located at both ends of the plurality of two-dimensional semiconductor layers 150.

Next, referring to FIG. 10B, an open channel region 155B′ of two-dimensional semiconductor layers 150B′ may be processed with plasma.

A void (V) may be formed in the channel region 155B′ by the present plasma processing. The void (V) may be provided as a site for phosphorus to be diffused in a subsequent process. The plasma may include Ar, H₂, and/or O₂ plasma.

Next, referring to FIG. 10C, a phosphorus film (not shown) may be deposited on the channel region 155B, and a capping layer may be formed on the deposited phosphorus film (not shown). The capping layer may be provided as a first dielectric film 161, and then a second dielectric film 162 and a gate electrode 170 may be sequentially formed.

A deposition process of the phosphorus film (not shown) may include various deposition processes using at least one of PH₃, P₂O₅, and P₂O₃. During the deposition process of the phosphorus film, phosphorus may be easily diffused into the interior of the plasma-processed channel region 155B′. Next, a capping layer may be formed on the deposited phosphorus film. In the present embodiment, the capping layer may include silicon oxide, silicon oxynitride, or silicon nitride. Through an additional annealing process, phosphorus may diffuse into the interior of the channel region 155B and/or the capping layer to be almost absent. The second dielectric film 162 may be formed on the first dielectric film 161 to form a desired gate insulating layer 160A. Next, a gate electrode 170 may be formed on the gate insulating layer 160A. For example, the second dielectric film 162 may include at least one of aluminum oxide (Al₂O₃), hafnium oxide (HfO₂), and zirconium oxide (ZrO₂).

Subsequently, referring to FIG. 10D, the contact regions 156 of the two-dimensional semiconductor layers 150B′ may be opened by partially removing both end regions of the insulating separation portion 120, and a phosphorus film 185 may be deposited on the open contact regions 156. Subsequently, a silicon capping layer 186 may be formed on the deposited phosphorus film 185.

In this process, in the deposition process of the phosphorus film 185, the desired phosphorus film 185 may be deposited more stably by depositing a phosphorus precursor 181 in the contact regions 156 of the two-dimensional semiconductor layer 150 in advance. For example, the phosphorus precursor 181 may include DIPAS, and may be deposited by plasma enhanced chemical vapor deposition (PECVD). The deposition process of the phosphorus film 185 may be performed by various deposition processes using at least one of PH₃, P₂O₅, and P₂O₃. Subsequently, a silicon capping layer 186 may be formed on the phosphorus film 185. In some example embodiments, the phosphorus precursor 181 and the phosphorus film 185 may be formed not only on surfaces of the contact regions 156, but also on an outer side wall of the insulating separation portion 120.

Next, referring to FIG. 10E, an annealing process may be applied to the phosphorus film 185 covered with the silicon capping layer 186. In the annealing process, phosphorus may also be diffused into the silicon capping layer 186 to form a contact resistance reduction layer 180 including SiP.

Subsequently, referring to FIG. 10F, source and drain electrodes 190 may be formed on the contact resistance reduction layer 180.

For example, each of the source and drain electrodes 190 may include a metal material such as Ag, Au, Pt, or Cu. The contact resistance reduction layer 180 may effectively reduce the contact resistance between the source/drain electrodes 190 and the two-dimensional semiconductor layer 150.

FIGS. 11A to 11I are cross-sectional views of major processes, illustrating a method for manufacturing a semiconductor device according to example embodiments of the present inventive concept, and may be understood as, for example, the method for manufacturing the semiconductor device 100C of FIG. 7.

Referring to FIG. 11A, after forming an insulating support layer 130 on a substrate 101, a trench (T) may be formed, and a two-dimensional semiconductor layer 150 may be formed on the insulating support layer 130.

An insulating support layer 130 may be formed on a substrate, and a trench (T) may be formed to remove a portion of the insulating support layer 130. A width of the trench (T) may define a length of the channel region 155 of the two-dimensional semiconductor layer 150. A portion located on the insulating support layer 130 in the two-dimensional semiconductor layer 150 may be provided as contact regions 156.

Next, referring to FIG. 11B, two-dimensional semiconductor layers 150C′ may be processed with plasma.

Unlike the previous embodiments, plasma processing may be applied not only to the channel region 155C′ of the two-dimensional semiconductor layers 150C′, but also to contact regions 156C′. In the present plasma processing, voids (V) may be formed in the two-dimensional semiconductor layers 150. The voids (V) may be provided to a site for phosphorus diffusion in subsequent processes. The plasma may include Ar, H₂, and/or O₂ plasma.

Next, referring to FIG. 11C, a process of doping phosphorus into a two-dimensional semiconductor layer 150C may be performed.

The doping process of phosphorus may be performed by a deposition process using at least one of PH₃, P₂O₅, and P₂O₃ on the two-dimensional semiconductor layer 150C, similar to the process illustrated in FIG. 10C. During the deposition process of the phosphorus film, phosphorus may diffuse into the channel region 155C as well as the contact regions 156C of the plasma-processed two-dimensional semiconductor layer 150C.

Next, referring to FIG. 11D, by additionally repeating the processes of FIGS. 11A to 11C several times (e.g., twice), three two-dimensional semiconductor layers 150C doped with phosphorus may be formed.

Next, referring to FIG. 11E, a capping layer may be formed on the two-dimensional semiconductor layers 150C, and the capping layer may be provided as a first dielectric film 161.

In the present embodiment, the capping layer may include silicon oxide, silicon oxynitride, or silicon nitride. Through an additional annealing process, phosphorus may diffuse into the interior of the channel region 155C and/or the capping layer to be almost absent. In the present embodiment, the capping layer may also be formed on a side surface and an upper surface of the insulating support layer 130.

Next, referring to FIG. 11F, a second dielectric film 162 and a gate electrode 170 may be sequentially formed on a channel region 155C.

The second dielectric film 162 may be formed on the first dielectric film 161 to form a desired gate insulating layer 160C. Subsequently, a gate electrode 170 may be formed on the gate insulating layer 160C. For example, the second dielectric film 162 may include at least one of aluminum oxide (Al₂O₃), hafnium oxide (HfO₂), and zirconium oxide (ZrO₂).

Next, referring to FIG. 11G, an insulating filling portion 140 may be formed around the channel region 155C surrounded by the gate electrode 170. Subsequently, an insulating support layer 130 may be removed to open contact regions 156C, and an insulating barrier 120C may be formed on outer sidewalls of the gate electrode 170 and the insulating filling portion 140. Next, referring to FIG. 11H, the semiconductor device 100C illustrated in FIG. 7 may be manufactured by forming source and drain electrodes 190 on the contact regions 156C.

For example, each of the source and drain electrodes 190 may include a metal material such as Ag, Au, Pt, or Cu. The insulating barrier 120C may be provided as a structure electrically separating the gate electrode 170 from the source and drain electrodes 190.

According to the example embodiments described above, in a semiconductor device, by using phosphorous doping, contact resistance between a two-dimensional semiconductor layer and a source/drain electrode (metal contact) may be improved, or channel mobility in a channel region of the two-dimensional semiconductor layer may be increased.

The various and beneficial advantages and effects of the present inventive concept are not limited to the above-described content, and may be more easily understood through description of specific embodiments of the present inventive concept.

While example embodiments have been illustrated and described above, it will be apparent to those skilled in the art that modifications and variations could be made without departing from the scope of the present inventive concept as defined by the appended claims.

What is claimed is:

1. A semiconductor device, comprising:
a two-dimensional semiconductor layer including a channel region, and contact regions on both sides of the channel region;
a gate electrode surrounding the channel region of the two-dimensional semiconductor layer;
a gate insulating layer disposed between the channel region of the two-dimensional semiconductor layer and the gate electrode;
a source electrode and a drain electrode respectively disposed in the contact regions of the two-dimensional semiconductor layer; and
a contact resistance reduction layer disposed between the contact regions and the source and drain electrodes, the contact resistance reduction layer including a semiconductor material doped with phosphorus.

2. The semiconductor device of claim 1, wherein the contact resistance reduction layer includes silicon phosphide (SiP).

3. The semiconductor device of claim 1, further comprising:
an insulating separation portion disposed on the contact region, adjacent to the channel region, and electrically separating the gate electrode from the source and drain electrodes.

4. The semiconductor device of claim 1, wherein the channel region comprises a two-dimensional semiconductor material doped with phosphorus.

5. The semiconductor device of claim 4, wherein the gate insulating layer comprises a plurality of dielectric films.

6. The semiconductor device of claim 5, wherein a dielectric film among the plurality of dielectric films, in contact with a surface of the channel region comprises a silicon compound layer.

7. The semiconductor device of claim 6, wherein the silicon compound layer comprises silicon phosphide (SiP), silicon oxide, silicon oxynitride, or silicon nitride.

8. The semiconductor device of claim 1, wherein the two-dimensional semiconductor layer comprises a plurality of two-dimensional semiconductor layers.

9. The semiconductor device of claim 8, wherein the two-dimensional semiconductor layer comprises at least one of graphene, hexagonal boron nitride (h-BN), MOS₂, WS₂, MoSe₂, WSe₂, and MoTe₂.

10. The semiconductor device of claim 1, wherein the two-dimensional semiconductor layer comprises Transition Metal Dichalcogenide (TMD).

11. The semiconductor device of claim 10, wherein the TMD comprises one metal element selected from the group consisting of Mo, W, Nb, V, Ta, Ti, Zr, Hf, Co, Tc, and Re and one chalcogen element selected from the group consisting of S, Se, and Te.

12. A semiconductor device, comprising:
a plurality of two-dimensional semiconductor layers including a channel region doped with phosphorus, and contact regions on both sides of the channel region, respectively;
a gate electrode surrounding the channel region of each of the plurality of two-dimensional semiconductor layers;
a gate insulating layer disposed between the channel region of each of the plurality of two-dimensional semiconductor layers and the gate electrode, the gate insulating layer including a plurality of dielectric films; and
a source electrode and a drain electrode respectively disposed in the contact regions of the plurality of two-dimensional semiconductor layers.

13. The semiconductor device of claim 12, wherein a dielectric film among the plurality of dielectric films, in contact with a surface of the channel region comprises a silicon compound layer.

14. The semiconductor device of claim 13, wherein the silicon compound layer comprises silicon phosphide (SiP), silicon oxide, silicon oxynitride, or silicon nitride.

15. The semiconductor device of claim 13, wherein the other dielectric film of the plurality of dielectric films comprises at least one of aluminum oxide, hafnium oxide, zirconium oxide, and a compound thereof.

16. The semiconductor device of claim 12, wherein the contact regions comprise a two-dimensional semiconductor material, not doped with phosphorus.

17. The semiconductor device of claim 12, further comprising:
an insulating separation portion disposed between the gate electrode, and the source and drain electrodes.

18. A semiconductor device, comprising:
a plurality of two-dimensional semiconductor layers including a channel region doped with phosphorus, and contact regions on both sides of the channel region, respectively;
a gate electrode surrounding the channel region of each of the plurality of two-dimensional semiconductor layers;
a gate insulating layer disposed between the channel region of each of the plurality of two-dimensional semiconductor layers and the gate electrode;
a source electrode and a drain electrode disposed in the contact regions of the plurality of two-dimensional semiconductor layers;
a contact resistance reduction layer disposed between the contact regions of the plurality of two-dimensional semiconductor layers, and the source electrode and the drain electrode, the contact resistance reduction layer including a semiconductor material doped with phosphorus; and
an insulating separation portion disposed between the gate electrode, and the source and drain electrodes in the plurality of two-dimensional semiconductor layers.

19. The semiconductor device of claim 18, wherein the contact resistance reduction layer comprises SiP.

20. The semiconductor device of claim 19, wherein the gate insulating layer comprises a plurality of dielectric films, and
a dielectric film among the plurality of dielectric films, in contact with a surface of the channel region includes a silicon compound layer.
